(19) United States
(12) Patent Application Publication
(10) Pub. No.: US 2016/0011937 A1
(43) Pub. Date: Jan. 14, 2016

(54) SEMICONDUCTOR MEMORY DEVICE, MEMORY CONTROLLER, AND CONTROL METHOD OF MEMORY CONTROLLER

(71) Applicant: KABUSHIKI KAISHA TOSHIBA, Minato-ku (JP)

(72) Inventors: Hironobu MIYAMOTO, Yokohama (JP); Ryoichi Kato, Kawasaki (JP); Tomonori Masuo, Kawasaki (JP)

(73) Assignee: KABUSHIKI KAISHA TOSHIBA, Minato-ku (JP)

(21) Appl. No.: 14/480,028

(22) Filed: Sep. 8, 2014

(30) Foreign Application Priority Data
Jul. 10, 2014 (JP) 2014-142206

(51) Int. Cl. G06F 11/10; G11C 29/52

(52) U.S. Cl. CPC G06F 11/1068; G11C 29/52

(57) ABSTRACT

In a semiconductor memory device of an embodiment, a controller writes write data and first address management information including address information of the write data to a memory, and performs, when an error occurs in any of the write data read from the memory, an error correction process to an error correction group including the write data and the first address management information. The controller generates, when a read error is detected within a process target error correction group, second address management information including address information of write data within the process target error correction group and error position information indicative of a position of the read error, and writes invalid data and the second address management information to erased condition areas within areas to be written of the process target error correction group.

### CROSS-REFERENCE TO RELATED APPLICATIONS

This application is based upon and claims the benefit of priority from Japanese Patent Application No. 2014-142206, filed Jul. 10, 2014, the entire contents of which are incorporated herein by reference.

### FIELD

Embodiments described herein relate generally to a semiconductor memory device, a memory controller, and a control method of the memory controller.

### BACKGROUND

As an example of a nonvolatile semiconductor memory, a NAND flash memory is used. To increase a reliability of data written in the NAND flash memory, a technique of generating an error correction code based on data received from a host device, and writing the data and the generated error correction code to the NAND flash memory, is used.

In general, the error correction code and the data are written to the NAND flash memory simultaneously.

In a semiconductor memory device which writes small mount of data at a time, a timing of writing the data and a timing of writing the error correction code may be separated for limiting so that a ratio of the error correction code to the data to be written corresponds to an error occurrence probability. For example, after a certain amount of data is written, an error correction code corresponding to the amount of written data is written.

### BRIEF DESCRIPTION OF THE DRAWINGS

FIG. 1 is a block diagram showing an example of a structure of a semiconductor memory device according to a first embodiment;

FIG. 2 is a view showing an example of a parallel write of page data to a nonvolatile semiconductor memory in a semiconductor memory device of a comparative example;

FIG. 3 is a view showing an example of a condition of the nonvolatile semiconductor memory when an abnormal power shutdown occurs during a write process in the semiconductor memory device of the comparative example;

FIG. 4 is a view showing an example of a condition of the nonvolatile semiconductor memory when power is resupplied after the abnormal power shutdown in the semiconductor memory device of the comparative example;

FIG. 5 is a view showing an example of a condition of the nonvolatile semiconductor memory when the abnormal power shutdown occurs, power is resupplied, and an initialization process is performed;

FIG. 6 is a view showing an example of a content of address management information according to the first embodiment;

FIG. 7 is a flowchart showing an example of the initialization process of the semiconductor memory device according to the first embodiment;

FIG. 8 is a flowchart showing an example of an error correction process with respect to an initialization target block of the semiconductor memory device according to the first embodiment; and

FIG. 9 is a block diagram showing an example of a storage device according to a second embodiment.

### DETAILED DESCRIPTION

In general, according to one embodiment, a semiconductor memory device includes a nonvolatile semiconductor memory and a memory controller. The memory controller writes a plurality of write data and first address management information including address information of the plurality of write data to the nonvolatile semiconductor memory, and performs, when an error occurs in any of the plurality of write data read from the nonvolatile semiconductor memory, an error correction process to an error correction group including the plurality of write data and the first address management information. The memory controller generates, when a read error is detected within a process target error correction group, second address management information including address information of write data within the process target error correction group and error position information indicative of a position of the read error, and writes invalid data and the second address management information to erased condition areas within areas to be written of the process target error correction group.

Embodiments will be described hereinafter with reference to drawings. In a following description, the same reference numerals denote components having nearly the same functions and elements, and a repetitive description thereof will be given if necessary.

### First Embodiment

A semiconductor memory device of the present embodiment reads data written to a nonvolatile semiconductor memory when the semiconductor memory device is restarted after an abnormal power shutdown of the semiconductor memory device. Then, the semiconductor memory device writes invalid data to an erased condition area, generates address management information and error correction code corresponding to the read data, and writes the address management information and the error correction code to the nonvolatile semiconductor memory.

In the present embodiment, the address management information generated at a time of a restart after the abnormal power shutdown includes, for example, address information associating a page position (page number or page address) with logical block addressing (LBA) of the data stored in the page, and error position information indicative of a position (page) of an error due to the abnormal power shutdown during a write process.

In the present embodiment, a process performed when a read error occurs in the nonvolatile semiconductor memory is explained. In the following description, exemplified is a case where an abnormal power shutdown occurs during a write process in the nonvolatile semiconductor memory and a read error occurs in a subsequent read process. Note that no limitation is intended by the above, and the present embodiment is applicable to cases where a read error occurs in the nonvolatile semiconductor memory for any other reason, for example, a case where a write process is performed normally but an error occurs in a read process, and the like.

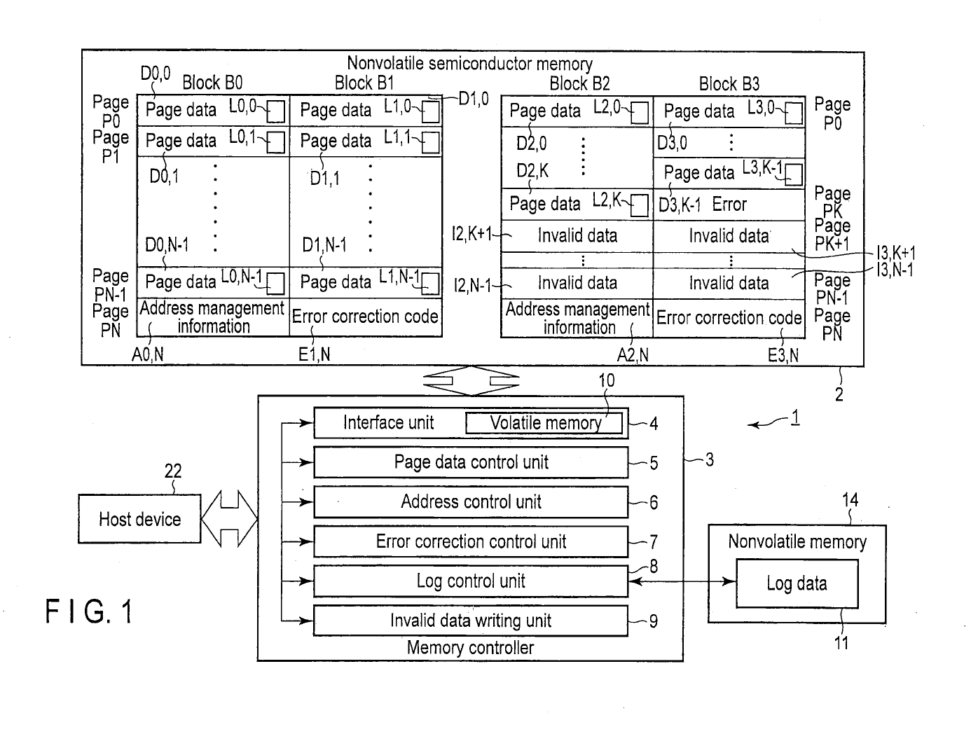

FIG. 1 is a block diagram showing an example of a structure of a semiconductor memory device according to the present embodiment.

A semiconductor memory device 1 includes a nonvolatile semiconductor memory 2, memory controller 3, and nonvolatile memory 14. In the present embodiment, the nonvolatile semiconductor memory 2 and the nonvolatile memory 14 are separated from each other; however, the nonvolatile semiconductor memory 2 and the nonvolatile memory 14 may be formed integrally instead.

The nonvolatile semiconductor memory 2 is, for example, a NAND flash memory. However, the nonvolatile semiconductor memory 2 may be, for example, a NOR flash memory, a magnetoresistive random access memory (MRAM: magnetoresistive memory), a phase change random access memory (PRAM: phase change memory), a resistive random access memory (ReRAM: resistive change memory), or a ferroelectric random access memory (FeRAM).

In the present embodiment, write data is written to a page of the nonvolatile semiconductor memory 2 by a page size. In the present embodiment, data of a page size is referred to as page data. The page data includes address information such as LBA or the like corresponding to the page data itself.

In the nonvolatile semiconductor memory 2, data is erased on a block-by-block basis. A block includes a plurality of pages.

In the present embodiment, when an error occurs in the read process of the write data written to the nonvolatile semiconductor memory 2, an error correction process is performed with respect to an error correction group including the write data in which the error has occurred.

Here, the error correction group includes a plurality of write data and address management information based on address information of the plurality of write data.

For example, the error correction group includes a plurality of page data sets. Each of the page data sets includes two or more page data written in parallel to the nonvolatile semiconductor memory 2.

More specifically, in the present embodiment, the error correction group is a block set including a plurality of blocks to which writes of a plurality of page data are performed in parallel.

The memory controller 3 receives the data from a host device 22 and writes the data to the nonvolatile semiconductor memory 2. Furthermore, the memory controller 3 reads the data from the nonvolatile semiconductor memory 2 in response to a read command from the host device 22 and sends the read data to the host device 22.

The memory controller 3 includes an interface unit 4, page data control unit 5, address control unit 6, error correction control unit 7, log control unit 8, and invalid data writing unit 9. Each of the structural elements of the memory controller 3 may be implemented by executing a firmware.

The interface unit 4 receives various data (such as page data, address management information, error correction code, and invalid data) from the other structural elements of the memory controller 3, stores the various data in a volatile memory 10 such as a dynamic random access memory (DRAM) or the like, and writes the various data stored in the volatile memory 10 to the nonvolatile semiconductor memory 2.

Furthermore, the interface unit 4 reads various data from the nonvolatile semiconductor memory 2, stores the various data in the volatile memory 10, and sends the various data stored in the volatile memory 10 to the other structural elements of the memory controller 3.

In the present embodiment, the interface unit 4 is structured to include the volatile memory 10; however, the interface unit 4 and the volatile memory 10 may be separated from each other.

The page data control unit 5 controls a write process of page data to the nonvolatile semiconductor memory 2. In the present embodiment, the page data control unit 5 writes two page data in parallel to two blocks of the nonvolatile semiconductor memory 2 through the interface unit 4. Note that the page data control unit 5 may write three or more page data in parallel to three or more blocks instead.

Specifically, the page data control unit 5 firstly writes page data D0,0 to page P0 of block B0 and page data D1,0 to page P0 of block B1 through the interface unit 4.

Secondly, the page data control unit 5 writes page data D0,1 to page P1 of the block B0 and page data D1,1 to page P1 of the block B1 through the interface unit 4.

Thereafter, the page data control unit 5 similarly writes, through the interface unit 4, page data D0,2 to D0,N−1 to pages P2 to PN−1 of the block B0 and writes page data D1,2 to D1,N−1 to pages P2 to PN−1 of the block B1 in parallel with the page data D0,2 to D0,N−1, respectively one after another.

When a predetermined number of the page data D0,0 to D0,N−1 and D1,0 to D1,N−1 are written to the nonvolatile semiconductor memory 2, the address control unit 6 generates address management information A0,N corresponding to the written page data D0,0 to D0,N−1 and D1,0 to D1,N−1. Then, the address control unit 6 writes the address management information A0,N to page PN of the block B0 in the nonvolatile semiconductor memory 2 through the interface unit 4.

The address management information is generated at every two or more parallel writes. In the present embodiment, explained is a case where the address management information is generated in every block set including a plurality of blocks to which writes are performed in parallel.

When a predetermined number of the page data D0,0 to D0,N−1 and D1,0 to D1,N−1 are written to the nonvolatile semiconductor memory 2, the error correction control unit 7 generates error correction code E1,N corresponding to the written page data D0,0 to D0,N−1 and D1,0 to D1,N−1. Then, the error correction control unit 7 writes the error correction code E1,N to page PN of the block B1 in the nonvolatile semiconductor memory 2.

When the semiconductor memory device 1 works normally, a process which is similar to the write process by the page data control unit 5, address control unit 6, and error correction control unit 7 with respect to the blocks B0, B1 is performed with respect to other plurality of blocks such as blocks B2, B3 and the like.

The log control unit 8 generates log data (for example, a journal) 11 including a history of the write with respect to an area (for example, blocks) of the nonvolatile semiconductor memory 2, and writes the log data 11 to the nonvolatile memory 14.

Note that the following is described given that an abnormal power shutdown occurs in the semiconductor memory device 1 during the write process of page PK of the block B3 and then the semiconductor memory device 1 is turned on.

The log control unit 8 reads the log data 11 stored in the nonvolatile memory 14. Then, the log control unit 8 determines in what block the abnormal power shutdown occurred and notifies the blocks B2 and B3 in which the write error occurred to the page data control unit 5, address control unit 6, error correction control unit 7, and invalid data writing unit 9.

The page data control unit 5 reads page data D2,0 to D2,K and D3,0 to D3,K−1 from page P0 to PN−1 of the blocks B2, B3 in which the write error occurred.

The address control unit 6 generates the address management information A2,N which includes address information L2,0 to L2,K and L3,0 to L3,K−1 corresponding to the page data D2,0 to D2,K and D3,0 to D3,K−1 read from the blocks B2 and B3 in which the write error occurred in the nonvolatile semiconductor memory 2 and error position information indicative of the position of the write error.

In the present embodiment, the page data D0,0 to D0,N−1, D1,0 to D1,N−1, D2,0 to D2,K, and D3,0 to D3,K−1 include their corresponding address information L0,0 to L0,N−1, L1,0 to L1,N−1, L2,0 to L2,K, and L3,0 to L3,K−1, respectively, as LBA or the like. Address management information A2,N corresponding to the blocks B2 and B3 in which the write error occurred is generated using the address information L2,0 to L2,K and L3,0 to L3,K−1 included in the page data D2,0 to D2,K and D3,0 to D3,K−1.

The error correction control unit 7 generates error correction code E3,N based on the page data D2,0 to D2,K and D3,0 to D3,K−1 read from the blocks B2, B3 in which the write error occurred in the nonvolatile semiconductor memory 2, invalid data I2,K+1 to I2,N−1 and I3,K+1 to I3,N−1 written to pages in the erased condition, and the address management information A2,N.

In the present embodiment, the error correction code E3,N is generated based on the page data D2,0 to D2,K and D3,0 to D3,K−1, the invalid data I2,K+1 to I2,N−1 and I3,K+1 to I3,N−1, and the address management information A2,N, but this is merely an example. The error correction code E3,N may be generated based on readable page data D2,0 to D2,K and D3,0 to D3,K−1 and address management information A2,N, or based on readable page data D2,0 to D2,K and D3,0 to D3,K−1 and invalid data I2,K+1 to I2,N−1 and I3,K+1 to I3,N−1, or based on the page data D2,0 to D2,K and D3,0 to D3,K−1 alone.

When the log control unit 8 detects a write error, the invalid data writing unit 9 writes, through the interface unit 4, the invalid data I2,K+1 to I2,N−1 and I3,K+1 to I3,N−1 to the pages PK+1 to PN−1 in the erased condition of the blocks B2 and B3 to which the write is performed after page PK of an initialization target block B3 where an error (not written page data) occurred.

The address control unit 6 writes the address information A2,N to the page PN of the block B2 in the nonvolatile semiconductor memory 2.

The error correction control unit 7 writes the error correction code E3,N to page PN of the block B3 in the nonvolatile semiconductor memory 2.

Furthermore, when a read error is detected in any of the page data D2,0 to D2,K and D3,0 to D3,K−1 within the initialization target blocks B2, B3 in which the write error occurred, the error correction control unit 7 excludes the page PK of the block B3 indicated by the error position information of the address management information A2,N from the target of error correction process, and then performs the error correction process with respect to the page data D2,0 to D2,K and D3,0 to D3,K−1 based on the error correction code E3,N.

Hereinafter, a semiconductor memory device of a comparative example and the semiconductor memory device 1 of the present embodiment are compared.

When an abnormal power shutdown occurs during an execution of a write process in which a timing of writing page data and a timing of writing error correction code are separated and power is supplied next, the nonvolatile semiconductor memory 2 is not storing an error correction code corresponding to page data written between the last written error correction code and the abnormal power shutdown. Thus, a reliability of the page data written between the last written error correction code and the abnormal power shutdown is decreased.

As a data density increases by miniaturization of the nonvolatile semiconductor memory 2, a reliability of the page data written in the nonvolatile semiconductor memory 2 tends to decrease. As methods to keep a reliability of the nonvolatile semiconductor memory 2, limiting the amount of write to the nonvolatile semiconductor memory 2, and limiting the use of nonvolatile semiconductor memory 2 are available. Specifically, the data reliability of the nonvolatile semiconductor memory 2 is kept by not leaving an erased area in a non-written condition for a long time. Or, when a non-written page due to an abnormal power shutdown is detected in a block during the write process, a re-erase with respect to an erased condition area (for example, a page) is prevented by completing the write process with respect to the non-written page in the block during the write process such that the reliability of the data of the nonvolatile semiconductor memory 2 is kept.

Furthermore, in the block which was being subjected to the write process at the time of the abnormal power shutdown, an error may occur in data of the page being written and such block may not be used continuously. Thus, in the block which was being subjected to the write process at the time of the abnormal power shutdown, invalid data is written in the remainder of the pages in the block to complete the write process.

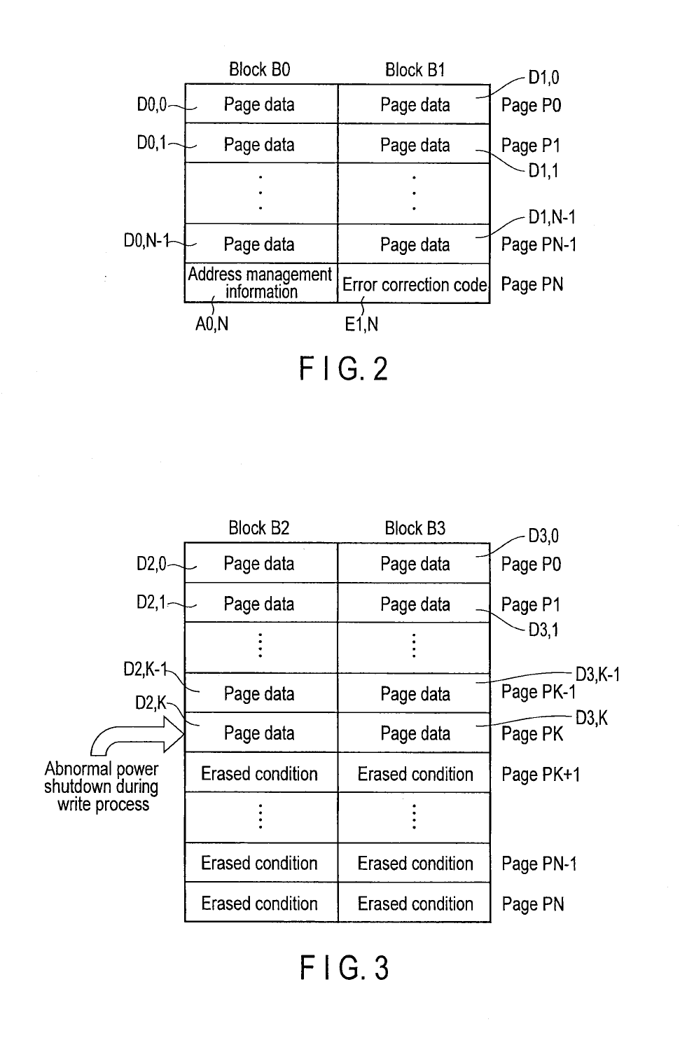

Firstly, the semiconductor memory device of the comparative example is explained with reference to FIGS. 2 to 4.

FIG. 2 shows an example of a parallel write of page data in a nonvolatile semiconductor memory according to the semiconductor memory device of the comparative example.

The semiconductor memory device of the comparative example writes the page data D0,0 to D0,N−1 and D1,0 to D1,N−1 in parallel with respect to the pages P0 to PN−1 of two blocks B0, B1 in the nonvolatile semiconductor memory 2. After writing a certain number of the page data D0,0 to D0,N−1 and D1,0 to D1,N−1 to the nonvolatile semiconductor memory 2, the semiconductor memory device of the comparative example writes the address management information A0,N indicative of address information of each page data D0,0 to D0,N−1 and D1,0 to D1,N−1 and the error correction code E1,N used to correct each of the page data D0,0 to D0,N−1 and D1,0 to D1,N−1 and the address management information A0,N to the nonvolatile semiconductor memory 2. FIG. 2 shows that the address management information and the error correction code are written in each of a plurality of blocks written in parallel as in FIG. 1.

FIG. 3 is a view showing an example of a condition of the nonvolatile semiconductor memory 2 when an abnormal power shutdown occurs during a write process in the semiconductor memory device of the comparative example.

The semiconductor memory device of the comparative example writes the page data D2,0 to D2,K−1 and D3,0 to D3,K−1 to the pages P0 to PK−1 of the two blocks B2 and B3 of the nonvolatile semiconductor memory 2.

Now, FIG. 3 shows that an abnormal power shutdown occurs during the write process of the page data D2,K and D3,K with respect to the page PK of the blocks B2 and B3. In this case, the pages PK+1 to PN of the blocks B2 and B3 which are not subjected to the write process are in the erased condition. In the condition shown in FIG. 3, address management information and error correction code are not written in the block B2 or B3. Therefore, the page data D2,0 to D2,K−1 and D3,0 to D3,K−1 already written in the blocks B2 and B3 have less error correction performance as compared with that of the other page data written in the other blocks.

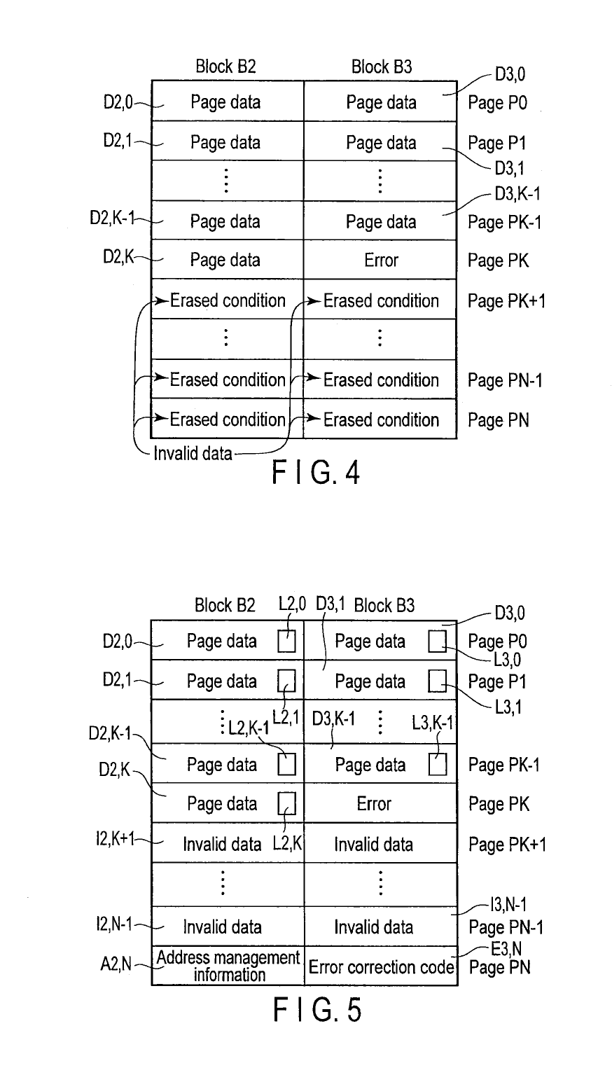

FIG. 4 is a view showing an example of a condition of the nonvolatile semiconductor memory 2 when power is resupplied after the abnormal power shutdown in the semiconductor memory device of the comparative example.

A normal read process cannot be performed with respect to the page PK of the block B3 in which the abnormal power shutdown occurred during the write process, and an error may occur during the read of the page PK of the block B3. Furthermore, when the abnormal power shutdown occurs during a write process, a reliability of the write to the pages PK+1 to PN in the erased condition of the blocks B2 and B3 may decrease.

Considering the above, the semiconductor memory device of the comparative example does not use the block B2 or B3 continuously, but writes invalid data to the remaining pages PK+1 to PN to the erased condition of the blocks B2 and B3 and stops the use of the blocks B2 and B3.

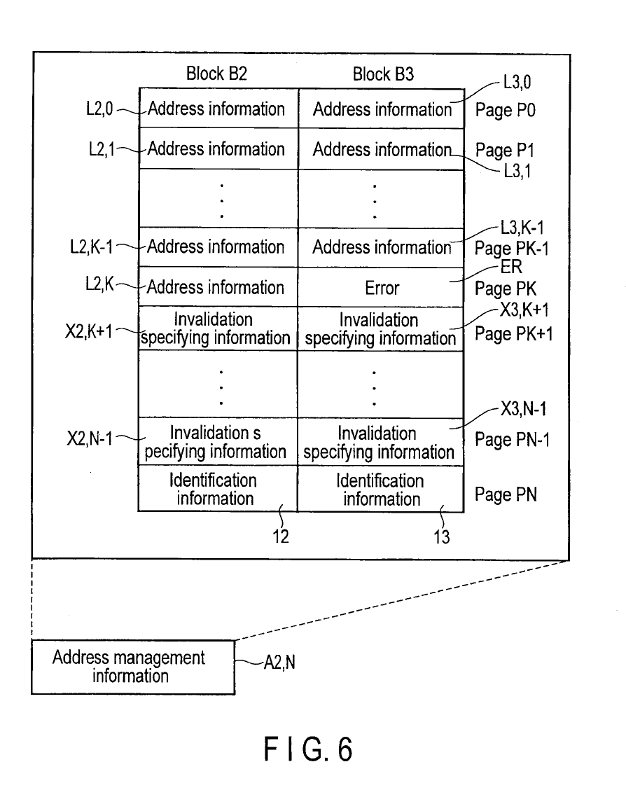

Now the semiconductor memory device 1 of the present embodiment is explained with reference to FIGS. 5 and 6 for a comparison.

FIG. 5 is a view showing an example of a condition of the nonvolatile semiconductor memory 2 when the abnormal power shutdown occurs, power is resupplied, and an initialization process is performed.

An initialization process according to the present embodiment is performed by the log control unit 8, page data control unit 5, address control unit 6, error correction control unit 7, and invalid data writing unit 9.

In the initialization process performed at a time of the power resupply, the blocks B2 and B3 in which non-written pages PK+1 to PN occurred due to an abnormal power shutdown during the write process are detected, and a read process for the page data D2,0 to D2,K and D3,0 to D3,K−1 is performed with respect to the blocks B2 and B3.

In the initialization process, the address management information A2,N is generated based on the address information L2,0 to L2,K and L3,0 to L3,K−1 of the read page data D2,0 to D2,K and D3,0 to D3,K−1 and error position information.

In the initialization process, the error correction code E3,N corresponding to the read page data D2,0 to D2,K and D3,0 to D3,K−1, the invalid data I2,K+1 to I2,N−1 and I3,K+1 to I3,N−1 written in the pages PK+1 to PN−1 in the erased condition of the blocks B2 and B3, and the address management information A2,N is generated.

Then, in the initialization process, the invalid data I2,K+1 to I2,N−1 and I3,K+1 to I3,N−1, the address management information A2,N, and the error correction code E3,N are written in the pages PK+1 to PN in the erased condition of the blocks B2 and B3.

FIG. 6 is a view showing an example of a content of the address management information A2,N according to the present embodiment.

The Address management information A2,N includes information indicative of a relationship between the address information (for example, LBA) L2,0 to L2,K and L3,0 to L3,K−1 of normally written page data D2,0 to D2,K and D3,0 to D3,K−1 and the written pages P0 to PK−1 of the blocks B2 and B3 in which the abnormal power shutdown occurred during the write process, error position information ER indicative of a position of the page PK of the block B3 in which the error occurred, invalidation specifying information X2,K+1 to X2,N−1 and X3,K+1 to X3,N−1 specifying the pages PK+1 to PN−1 to which the invalid data I2,K+1 to I2,N−1 and I3,K+1 to I3,N−1 are written, identification information 12 of the address management information A2,N corresponding to the blocks B2 and B3 in which the abnormal power shutdown occurred during the write process, and identification information 13 of the error correction code E3,N corresponding to the blocks B2 and B3 in which the abnormal power shutdown occurred during the write process.

The address management information A2,N is, for example, stored in the volatile memory 10 of the interface unit 4 and then written to the page PN of the block B2.

As the error correction code E3,N, a value of exclusive or (XOR) with respect to the other page than the page PK of the block B3 in which the write error occurred in a set of a plurality of blocks B2 and B3 to which the write process is performed in parallel.

In a method of the comparative example, the XOR data with respect to the set of page data written in parallel is calculated in every single parallel write with respect to the plurality of blocks, and the calculated XOR data is written in the nonvolatile semiconductor memory 2 as an error correction code.

In this method of the comparative example, an error correction process based on the error correction code is used only in the set of the page data in which the write is performed in parallel.

In contrast, in the present embodiment, the address management information and the error correction code are generated and written after a plurality of writes with respect to a plurality of blocks are performed in parallel. In the present embodiment, the page PK of the block B3 in which the error occurred is excluded preliminarily from the pages P0 to PN of the blocks B2 and B3, the calculation of the XOR data with respect to the pages P0 to PN of the block B2 and the pages P0 to PK−1 and PK+1 to PN−1 of the block B3 in which no error is detected, and the error correction code E3,N is generated and written in the page PN of the block B3.

As can be understood from the above, in the present embodiment, the page PK of the block B3 in which the error was detected is excluded from the target of the error correction process. Then, when an error occurs in the pages P0 to PN−1 of the block B2 and the pages P0 to PK−1 and PK+1 to PN−1 of the block B3 in which no error is detected, the error can be corrected based on the generated error correction code E3,N.

Therefore, the reliability of the data written in the nonvolatile semiconductor memory 2 can be increased in the present embodiment.

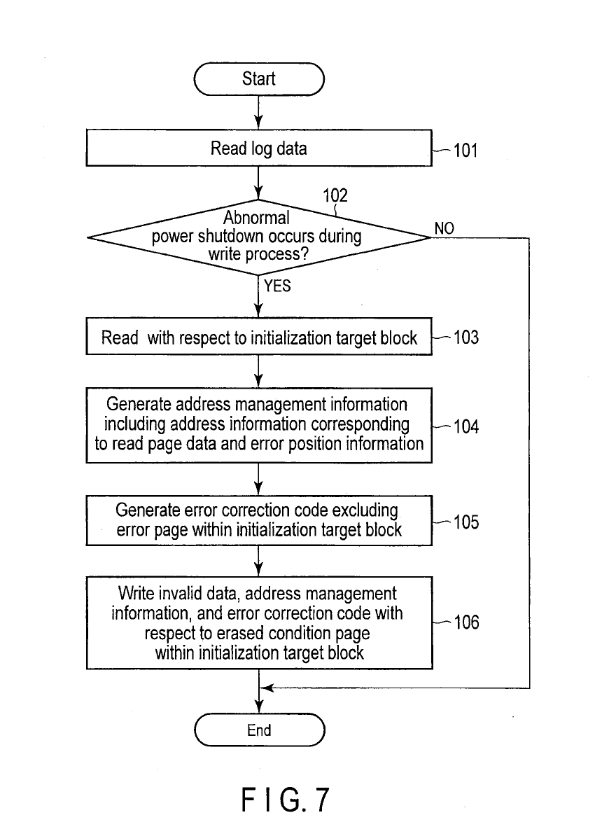

FIG. 7 is a flowchart showing an example of the initialization process of the semiconductor memory device 1 according to the present embodiment.

In block 101, the log control unit 8 reads the log data 11.

In block 102, the log control unit 8 determines whether or not an initialization target block in which an abnormal power shutdown occurred during a write process exists based on the read log data 11. When no initialization target block is detected, the process is terminated.

When the initialization target block is detected in block 102, the page data control unit 5 performs a read with respect to the initialization target block in block 103.

In block 104, the address control unit 6 generates address management information including address information corresponding to the page data read from the initialization target block and error position information of the position of the error in the write process.

In block 105, the error correction control unit 7 generates an error correction code corresponding to the pages within the initialization target block excluding the error page.

In block 106, the invalid data writing unit 9, address control unit 6, and error correction control unit 7 write the invalid data, address management information, and error correction code, respectively, with respect to pages in the erased condition within the initialization target block.

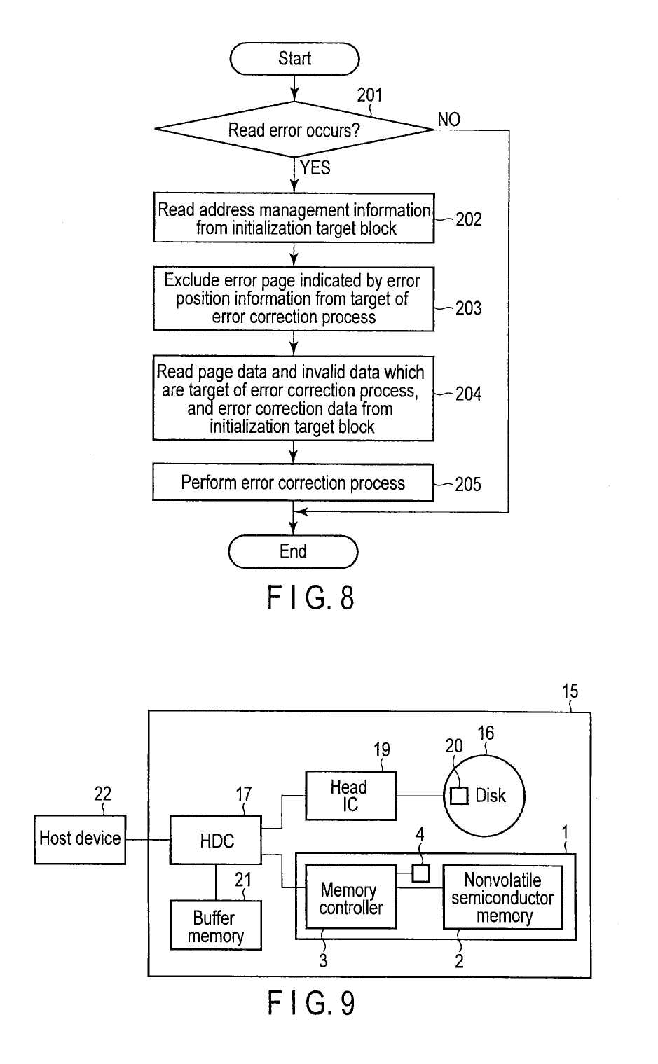

FIG. 8 is a flowchart showing an example of the error correction process with respect to the initialization target block of the semiconductor memory device 1 of the present embodiment.

In block 201, the error correction control unit 7 determines whether or not a read error occurred in a read process of any page data within the initialization target block.

When no read error is detected, the process is terminated.

When the read error is detected in block 201, the address control unit 6 reads address management information from the initialization target block in block 202.

In block 203, the error correction control unit 7 excludes an error page indicated by error position information of the address management information from the target of the error correction process.

In block 204, the page data control unit 5 reads page data and invalid data targeted for the error correction process from the initialization target block, and the error correction control unit 7 reads an error correction code from the initialization target block.

In block 205, the error correction control unit 7 performs the error correction process based on the page data, invalid data, address management information, and error correction code read from the initialization target block.

The above-explained semiconductor memory device 1 of the present embodiment detects the initialization target blocks B2 and B3 in which the abnormal power shutdown occurred during the write process in an activation process performed after the abnormal power shutdown. The semiconductor memory device 1 reads each of the page data D2,0 to D2,K and D3,0 to D3,K−1 of the initialization target blocks B2 and B3, and generates the address management information A2,N including the address information L2,0 to L2,K and L3,0 to L3,K−1 of the read page data D2,0 to D2,K and D3,0 to D3,K−1 and the error position information indicative of the position of the page in which the error occurred. The semiconductor memory device 1 writes the invalid data I2,K+1 to I2,N−1 and I3,K+1 to I3,N−1, the address management information A2,N, and the error correction code E3,N with respect to the pages PK+1 to PN in the erased condition of the initialization target blocks B2 and B3 at the time of activation for securing the data reliability of the nonvolatile semiconductor memory 2.

Thereby, a write process is completed to non-written pages PK+1 to PN of the initialization target blocks B2 and B3 in which the abnormal power shutdown occurred during the write process, and the data reliability of the nonvolatile semiconductor memory 2 can be secured. In the present embodiment, a time period between an erase and a write in the nonvolatile semiconductor memory 2 can be shortened.

In the present embodiment, the write of the address management information A2,N and the error correction code E3,N with respect to the nonvolatile semiconductor memory 2 are performed with consideration given to the initialization target block B2 and B3 including the invalid data I2,K+1 to I2,N−1 and I3,K+1 to I3,N−1. For example, the address management information A2,N and the error correction code E3,N are written in the nonvolatile semiconductor memory 2 without overlapping to the invalid data I2,K+1 to I2,N−1 and I3,K+1 to I3,N−1. The address management information A2,N and the error correction code E3,N are associated with each other. For example, the error correction code E3,N is used for the error correction process with respect to the pages of the initialization target blocks B2 and B3 excluding the page PK of the block B3 in which an error is occurring due to the abnormal power shutdown during the write process.

When a new read error is detected in any page data within the initialization target blocks B2 and B3 after the error correction code E3,N is written with respect to the nonvolatile semiconductor memory 2, the semiconductor memory device 1 of the present embodiment reads the address management information A2,N and the error correction code E3,N of the initialization target blocks B2 and B3. The semiconductor memory device 1 excludes the page PK of the initialization target block B3 in which the read error occurred due to the abnormal power shutdown from the target of the error correction process based on the error position information of the read address management information A2,N. Then, the semiconductor memory device 1 corrects the page data in which the new read error occurred performing the error correction process based on the error correction code E3,N.

Therefore, the data reliability of the nonvolatile semiconductor memory 2 can be increased.

In the present embodiment, the number of writes of the error correction code may be changed arbitrarily as long as it is less than the number of writes of the page data in parallel.

For example, varieties of the error correction code may be increased more than the present embodiment by, for example, preparing an error correction code for even numbered pages and an error correction code for odd numbered pages.

### Second Embodiment

In this embodiment, a storage device including the semiconductor memory device of the first embodiment is explained.

FIG. 9 is a block diagram showing a storage device including the semiconductor memory device of the present embodiment.

A storage device 15 is a hybrid hard disk drive (HDD), or may be other devices such as solid state drive (SSD) and the like.

The storage device 15 stores, based on a control by the host device 22, mass data in the nonvolatile semiconductor memory 2 and a disk 16 which is a magnetic recording medium.

The storage device 15 includes a hard disk controller (HDC) 17, buffer memory 21, head integrated circuit (IC) 19, disk 16, and head 20.

The HDC 17 controls an interface between the storage device 15 and the host device 22, and controls data write, data read, and the like to the nonvolatile semiconductor memory 2 and disk 16.

The buffer memory 21 temporally stores, based on a control by the HDC 17, write data or read data for data transfer between the storage device 15 and the host device 22. As the buffer memory 21, a DRAM is used for example.

The memory controller 3 controls the nonvolatile semiconductor memory 2 based on the control by the HDC 17.

The head IC 19 is a head amplifier integrated circuit to control the head 20 based on the control by the HDC 17.

The head 20 moves above the disk 16 based on a control by the head IC 19 to read the data stored in/write the data to the disk 16.

In the present embodiment, with the semiconductor memory device 1 in the storage device 15, the storage device 15 can improve a reliability of data stored in the storage device 15.

In such a hybrid storage device 15, an error correction can be performed even if the amount of page data which can be written in a single write with respect to the nonvolatile semiconductor memory 2 is small, a reliability of data in the nonvolatile semiconductor memory 2 can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a nonvolatile semiconductor memory; and
a memory controller configured to write a plurality of write data and first address management information including address information of the plurality of write data to the nonvolatile semiconductor memory, and when an error occurs in any of the plurality of write data read from the nonvolatile semiconductor memory, to perform an error correction process to an error correction group including the plurality of write data and the first address management information, wherein
the memory controller generates, when a read error is detected within a process target error correction group, second address management information including address information of write data within the process target error correction group and error position information indicative of a position of the read error, and writes invalid data and the second address management information to erased condition areas within areas to be written of the process target error correction group.

2. The semiconductor memory device of claim 1, wherein the memory controller generates, when the read error is detected in the process target error correction group, an error correction code corresponding to the process target error correction group, and writes the invalid data, the second address management information, and the error correction code to the erased condition areas within the areas to be written of the process target error correction group.

3. The semiconductor memory device of claim 2, wherein the memory controller reads, when a new read error for the write data within the process target error correction group is detected after the error correction code is written to the nonvolatile semiconductor memory, the second address management information and the error correction code, excludes an area indicated by the error position information from the error correction process target, and performs the error correction process to the write data within the process target error correction group based on the error correction code.

4. The semiconductor memory device of claim 1, wherein the write data is page data written to a page of the nonvolatile semiconductor memory,
the error correction group includes a plurality of page data, each of the plurality of page data including two or more page data written in parallel to the nonvolatile semiconductor memory, and
the read error is an error based on an abnormal power shutdown during a write process to the nonvolatile semiconductor memory.

5. The semiconductor memory device of claim 4, wherein the error correction group is a block set including a plurality of blocks to which writes of a plurality of page data are performed in parallel.

6. The semiconductor memory device of claim 1, wherein the memory controller comprises:
an interface unit configured to perform write and read of data to the nonvolatile semiconductor memory; and
a control unit configured to write the plurality of write data and the first address management information to the nonvolatile semiconductor memory through the interface unit and to perform the error correction process when the error occurs in any of the plurality of write data read from the nonvolatile semiconductor memory, wherein
the control unit generates, when the read error is detected in the process target error correction group, the second address management information based on the address information of the write data within the process target error correction group, and writes the invalid data and the second address management information to the erased condition areas within the areas to be written of the process target error correction group through the interface unit.

7. The semiconductor memory device of claim 1, wherein the memory controller generates log data including a write history with respect to each area in the nonvolatile semiconductor memory, writes the generated log data to a nonvolatile memory, and determines an area in which the read error is occurring within the process target error correction group based on the log data.

8. The semiconductor memory device of claim 1, wherein the write data includes respective address information, and
the memory controller generates the second address management information based on the address information included in the write data within the process target error correction group.

9. The semiconductor memory device of claim 1, further comprising:
a disk which is a magnetic memory medium; and
a controller which controls data writing and data reading between the semiconductor memory device and the disk.

10. A memory controller comprising:
an interface unit configured to perform write and read of data to a nonvolatile semiconductor memory; and
a control unit configured to write a plurality of write data and first address management information including address information of the plurality of write data to the nonvolatile semiconductor memory through the interface unit, and when an error occurs in any of the plurality of write data read from the nonvolatile semiconductor memory, to perform an error correction process to an error correction group including the plurality of write data and the first address management information, wherein
the control unit generates, when a read error is detected within a process target error correction group, second address management information including address information of write data within the process target error correction group and error position information indicative of a position of the read error, and writes invalid data and the second address management information to erased condition areas within areas to be written of the process target error correction group through the interface unit.

11. The memory controller of claim 10, wherein the control unit generates, when the read error is detected in the process target error correction group, an error correction code corresponding to the process target error correction group, and writes the invalid data, the second address management information, and the error correction code to the erased condition areas within the areas to be written of the process target error correction group.

12. The memory controller of claim 11, wherein the control unit reads, when a new read error for the write data within the process target error correction group is detected after the error correction code is written to the nonvolatile semiconductor memory, the second address management information and the error correction code, excludes an area indicated by the error position information from the error correction process target, and performs the error correction process to the write data within the process target error correction group based on the error correction code.

13. The memory controller of claim 10, wherein the write data is page data written to a page of the nonvolatile semiconductor memory,
the error correction group includes a plurality of page data, each of the plurality of page data including two or more page data written in parallel to the nonvolatile semiconductor memory, and
the read error is an error based on an abnormal power shutdown during a write process to the nonvolatile semiconductor memory.

14. A control method of a memory controller controlling write and read of data to a nonvolatile semiconductor memory, comprising:
writing a plurality of write data and first address management information including address information of the plurality of write data to the nonvolatile semiconductor memory;
performing, when an error occurs in any of the plurality of write data read from the nonvolatile semiconductor memory, an error correction process to an error correction group including the plurality of write data and the first address management information;
generating, when a read error is detected within a process target error correction group, second address management information including address information of write data within the process target error correction group and error position information indicative of a position of the read error; and
writing invalid data and the second address management information to erased condition areas within areas to be written of the process target error correction group.

15. The control method of claim 14, further comprising:
generating, when the read error is detected in the process target error correction group, an error correction code corresponding to the process target error correction group, and
writing the invalid data, the second address management information, and the error correction code to the erased condition areas within the areas to be written of the process target error correction group.

16. The control method of claim 15, further comprising:
reading, when a new read error for the write data within the process target error correction group is detected after the error correction code is written to the nonvolatile semiconductor memory, the second address management information and the error correction code; and
excluding an area indicated by the error position information from the error correction process target, and performing the error correction process to the write data within the process target error correction group based on the error correction code.

17. The control method of claim 14, wherein the write data is page data written to a page of the nonvolatile semiconductor memory,
the error correction group includes a plurality of page data, each of the plurality of page data including two or more page data written in parallel to the nonvolatile semiconductor memory, and
the read error is an error based on an abnormal power shutdown during a write process to the nonvolatile semiconductor memory.
